(19) United States
(12) Patent Application Publication
(10) Pub. No.: US 2026/0243924 A1
(43) Pub. Date: Aug. 20, 2026

(54) METHOD FOR MANUFACTURING WINDOW, DISPLAY DEVICE INCLUDING WINDOW MANUFACTURED BY THE SAME, AND ELECTRONIC DEVICE INCLUDING WINDOW

(71) Applicant: Samsung Display Co., LTD., Yongin-si (KR)

(72) Inventors: HYORIN LEE, Yongin-si (KR); KYONGBIN JIN, Yongin-si (KR)

(21) Appl. No.: 19/389,382

(22) Filed: Nov. 14, 2025

(30) Foreign Application Priority Data
Feb. 20, 2025 (KR) 10-2025-0022469

(51) Int. Cl. G02B 1/14; G06F 1/16

(52) U.S. Cl. CPC G02B 1/14; G06F 1/1652

(57) ABSTRACT

A method for manufacturing a window includes providing a substrate having a central portion and a side portion having a smaller thickness than the central portion on a plane, and forming a first light-blocking pattern on the substrate. The forming the first light-blocking pattern includes disposing, on the substrate, a mask which includes a printing region with a plurality of mesh patterns corresponding to the side portion and a portion of the central portion and a blocking region corresponding to a remaining portion of the central portion, providing ink on the printing region, and printing the ink on the substrate by using a squeegee which includes a body portion and a protruding portion having a slope surface inclined from one surface of the body portion and having a smaller thickness than the body portion.

This application claims priority to Korean Patent Application No. 10-2025-0022469, filed on February 20, 2025, and all the benefits accruing therefrom under 35 U.S.C. §119, the content of which in its entirety is herein incorporated by reference.

### BACKGROUND

### Field

The present disclosure herein relates to a method for manufacturing a window, a display device including a window manufactured by the method, and an electronic device including the window.

### Description of the Related Art

Display devices, for providing an image to a user, such as televisions, monitors, smart phones, and tablet personal computers (PCs) include a display panel that displays an image. Various display panels such as liquid crystal display panels, organic light-emitting display panels, electrowetting display panels, and electrophoretic display panels are being developed as a display panel. In addition, the display devices may include a window for protecting the display panel. The window may be attached to the display panel through a lamination process.

### SUMMARY

The present disclosure provides a method for manufacturing a window with improved printing quality of a light-blocking pattern.

The present disclosure also provides a display device including a window manufactured by a method for manufacturing a window with improved printing quality of a light-blocking pattern.

The present disclosure also provides an electronic device including the window.

An embodiment of the invention provides a method for manufacturing a window including providing a substrate including a central portion and a side portion having a smaller thickness than the central portion on a plane, and forming a first light-blocking pattern on the substrate, where the forming the first light-blocking pattern includes disposing, on the substrate, a mask which includes a printing region with a plurality of mesh patterns corresponding to the side portion and a portion of the central portion and a blocking region corresponding to a remaining portion of the central portion, providing ink on the printing region, and printing the ink on the substrate by using a squeegee which includes a body portion and a protruding portion having a slope surface inclined from one surface of the body portion and having a smaller thickness than the body portion.

In an embodiment, in the printing the ink on the substrate, the squeegee may pressurize the mask while moving in one direction.

In an embodiment, an angle between the slope surface of the squeegee and the one surface of the squeegee may be in a range from about 120 degrees to about 135 degrees.

In an embodiment, the printing region of the mask may be flexible, and the squeegee may pressurize the printing region along one direction such that the printing region is bent along the side portion.

In an embodiment, the ink may pass through the mesh pattern of the printing region, which is bent, and may be printed onto the central portion and the side portion.

In an embodiment, a width of a region, of the side portion of the substrate, exposed by the light-blocking pattern may be about 0.02 millimeter (mm) or less.

In an embodiment, the printing region may include a region which overlaps the substrate and a region which does not overlap the substrate.

In an embodiment, a thickness of the side portion may decrease as the side portion becomes further away from the central portion.

In an embodiment, a width of the side portion in a direction where the side portion is spaced apart from the central portion may be about 0.08 mm.

In an embodiment, the side portion may include a curved surface connected to the central portion.

In an embodiment, the side portion of the substrate may include a first portion connected to an upper surface of the central portion, a second portion connected to a lower surface of the central portion, and a third portion disposed between the first portion and the second portion, and a thickness of the first portion may decrease as being away from the central portion, a thickness of the second portion may decrease as being away from the central portion, and a thickness of the third portion may be constant as being away from the central portion.

In an embodiment, the method for manufacturing a window may further include forming a second light-blocking pattern on the first light-blocking pattern, wherein the forming of the second light-blocking pattern is formed by using an additional mask with a mesh pattern having a smaller size than the mesh pattern of the mask is defined.

In an embodiment, the second light-blocking pattern may expose at least a partial region of the first light-blocking pattern disposed on the side portion.

In an embodiment, the first light-blocking pattern may correspond to all edges of the substrate.

In an embodiment of the invention, a display device includes a window and a display module disposed on a lower surface of the window, where the window includes a substrate which has a central portion and a side portion having a smaller thickness than the central portion on a plane, and a light-blocking pattern disposed on the central portion and the side portion, the central portion includes an upper surface and a lower surface opposite to the upper surface, and the side portion includes a side surface disposed between the upper surface and the lower surface, a thickness of the side portion of the substrate decreases as being away from the central portion, and a width of the side portion in one direction where the side portion is spaced apart from the central portion is about 0.08 mm or less, and a width of a region of the side surface, which does not overlap the light-blocking pattern, in the one direction is about 0.02 mm or less.

In an embodiment, the side surface may include a plurality of planar surfaces, and the plurality of planar surfaces may include a first slope surface connected to the upper surface, a second slope surface connected to the lower surface, and a vertical surface connected between the first slope surface and the second slope surface.

In an embodiment, the side surface may be a curved surface.

In an embodiment, the light-blocking pattern may overlap a boundary between the upper surface of the central portion and the side surface of the side portion.

In an embodiment, the light-blocking pattern may extend along an edge of the substrate on the central portion.

In an embodiment of the invention, an electronic device includes a display device, a power module, and a processor, where the display device includes a window and a display module disposed on a lower surface of the window, the window includes a substrate which includes a central portion and a side portion having a smaller thickness than the central portion on a plane, and a light-blocking pattern disposed on the central portion and the side portion, the central portion includes an upper surface and a lower surface opposite to the upper surface, and the side portion includes a side surface disposed between the upper surface and the lower surface, a thickness of the side portion decreases as being away from the central portion, and a width of the side portion on a plane is about 0.08 mm or less, and a width of a region where the light-blocking pattern does not overlap the side portion is about 0.02 mm or less on a plane.

### BRIEF DESCRIPTION OF THE DRAWINGS

The above and other features of embodiments of the invention will become more apparent by describing in further detail embodiments thereof with reference to the accompanying drawings, in which:

FIG. 1 is a block diagram of an electronic device according to an embodiment;

FIG. 2 shows schematic diagrams of an electronic device according to various embodiments;

FIG. 3 is a perspective view of an electronic device according to an embodiment;

FIG. 4 is an exploded perspective view of a portion of an electronic device according to an embodiment;

FIG. 5 is a cross-sectional view taken along line I-I' of a window according to an embodiment;

FIG. 6 is a cross-sectional view taken along line I-I' of a window according to an embodiment;

FIGS. 7A to 7G are cross-sectional views illustrating a method for manufacturing a window according to an embodiment of the invention; and

FIG. 8 illustrates Comparative Examples of a squeegee according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or a region, a layer, a portion, or the like) is referred to as being "on", "connected to" or "coupled to" another element, it may be directly on, connected to, or coupled to the other element, or other elements may be disposed therebetween. In contrast, when an element is referred to as being “directly on”, “directly connected to”, or “directly coupled to” another element, there are no intervening elements present.

Like reference numerals or symbols refer to like elements throughout. Also, in the drawings, the thickness, ratio, and size of the elements are exaggerated for effectively describing the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, "about" can mean within one or more standard deviations, or within ± 30%, 20%, 10% or 5% of the stated value.

Unless otherwise defined, all terms (including technical and scientific terms) used herein have the same meaning as commonly understood by one of ordinary skills in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

A display device according to an embodiment may be applied to various electronic devices. An electronic device according to an embodiment may include the aforementioned display device, and may further include a module or device having another additional function other than the display device.

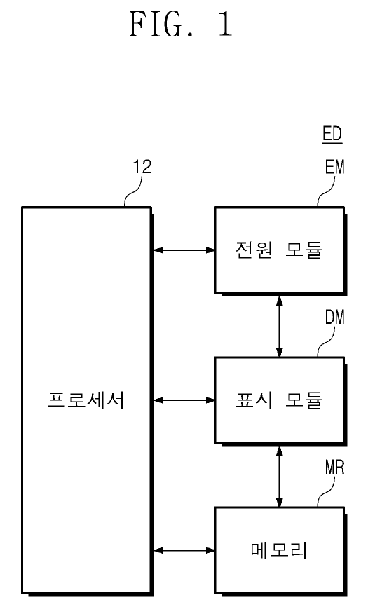

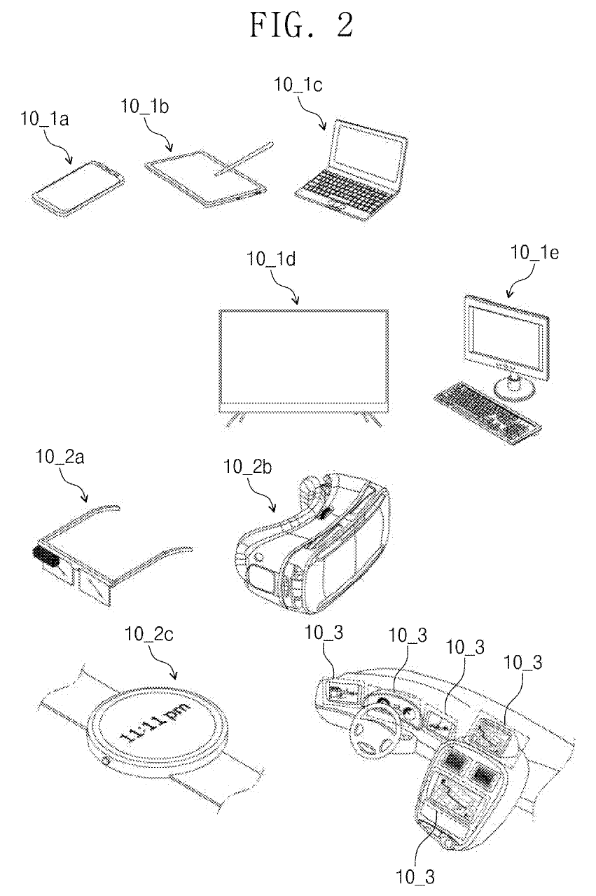

FIG. 1 is a block diagram of an electronic device according to an embodiment of the invention. FIG. 2 shows schematic diagrams of an electronic device according to various embodiments.

A display device according to an embodiment may be applied to various electronic devices. An electronic device according to an embodiment may include the aforementioned display device, and may further include a module or device having another additional function other than the display device.

FIG. 1 is a block diagram of an electronic device according to an embodiment of the invention. Referring to FIG. 1, an electronic device ED according to an embodiment may include a display module DM, a processor PR, a memory MR, and a power module EM.

The processor PR may include at least one selected from a central processing unit (CPU), an application processor (AP), a graphic processing unit (GPU), a communication processor (CP), an image signal processor (ISP), or a controller.

In the memory MR, data information used for an operation of the processor PR or the display module DM may be stored. When the processor PR executes an application stored in the memory MR, an image data signal and/or an input control signal may be transmitted to the display module DM, and the display module DM may process the received signal and output image information through a display screen.

The power module EM may include a power supply module such as a power adapter or battery unit, and a power conversion module which converts the power provided by the power supply module and generates power used for an operation of the electronic device ED.

At least one of the respective components of the electronic device ED described above may be included within the display device according to the aforementioned embodiments. In addition, some of individual modules functionally included within one module may be included within the display device, and others may be provided separately from the display device. In an embodiment, for example, the display device may include the display module DM, and the processor PR, the memory MR, and the power module EM may be provided as a form of another device within the electronic device ED other than the display device.

FIG. 2 shows schematic diagrams of an electronic device according to various embodiments.

Referring to FIG. 2, various electronic devices to which a display device according to embodiments is applied may include not only an electronic device for displaying an image such as a smart phone 10_1a, a tablet personal computer (PC) 10_1b, a laptop computer 10_1c, a television (TV) 10_1d, and a monitor 10_1e for a desk, but also a wearable electronic device including a display module such as smart glasses 10_2a, a head-mounted display 10_2b, and a smart watch 10_2c, and an electronic device 10_3 for vehicles including a display module such as a room mirror display and a center information display (CID), which is disposed on a car’s instrument cluster, center fascia, and dashboard.

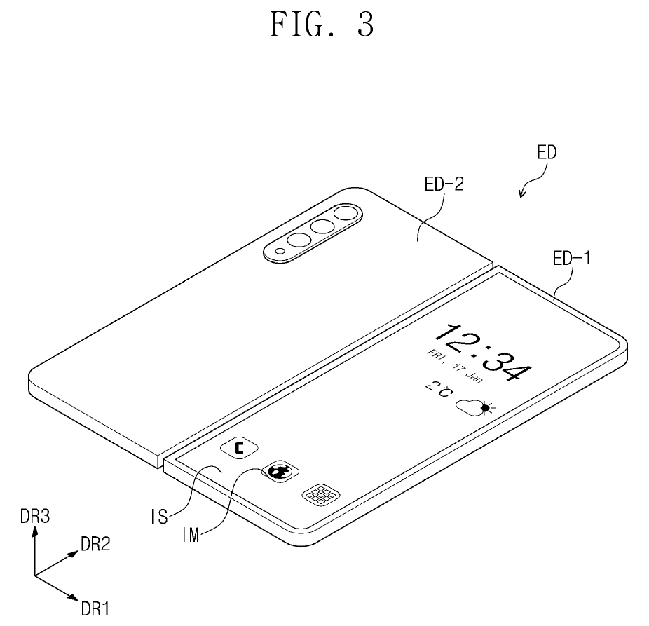

FIG. 3 is a perspective view of an electronic device according to an embodiment.

An electronic device according to an embodiment of the invention may include a flexible electronic module, for example, a flexible display module, a flexible touch module, a flexible solar cell module, or the like, which is capable of being operated stably even in a bent state by external force.

In an embodiment, an electronic device ED may have a rectangular shape having short sides extending in a first direction DR1 and long sides extending in a second direction DR2 crossing the first direction DR1. However, an embodiment of the invention is not limited thereto, and the electronic device ED may have various shapes such as a circular shape or polygonal shape. Hereinafter, a direction substantially perpendicularly crossing a plane defined by the first direction DR1 and the second direction DR2 is defined as a third direction DR3. In this specification, the wording “on a plane” is defined as a “state viewed in the third direction DR3”.

In an embodiment, the electronic device ED may be a foldable electronic device, as shown in FIG. 3. As illustrated in FIG. 3, an embodiment of the electronic device ED may include a first electronic device ED-1 and a second electronic device ED-2. The first electronic device ED-1 and the second electronic device ED-2 may be folded or foldable with respect to an axis that is parallel to the second direction DR2.

In an unfolded state of the electronic device ED, a display surface IS of the first electronic device ED-1 is exposed. As illustrated in FIG. 3, an image IM is displayed on the display surface IS. In FIG. 3, icon images are illustrated as an example of an image.

The display surface IS is illustrated on a surface where the first electronic device ED-1 is viewed from the third direction DR3, but the image IM may be displayed on a surface (not illustrated) of the first electronic device ED-1 located opposite to the display surface IS of the first electronic device ED-1 in the third direction DR3, and a surface located opposite to a displayed surface of the second electronic device ED-2 in the third direction DR3.

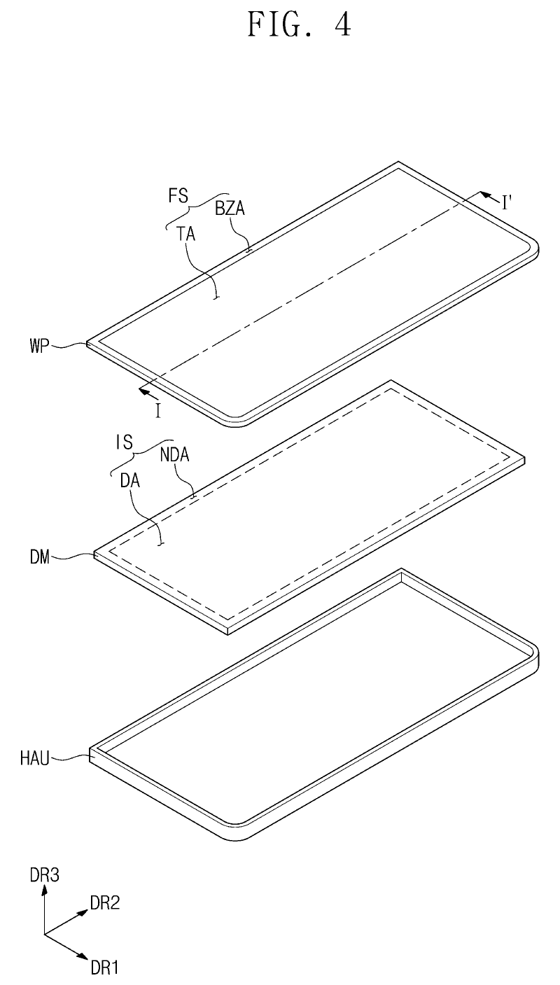

FIG. 4 is an exploded perspective view of a portion of an electronic device according to an embodiment. FIG. 4 schematically illustrates only the first electronic device ED-1 of the electronic device ED in FIG. 3.

In an embodiment, as illustrated in FIG. 4, an electronic device ED-1 includes a window WP, a display module DM, and a housing HAU. The display module DM may be disposed on a lower surface of the window WP, and the display module DM may be accommodated in the housing HAU.

The window WP is disposed on the display module DM to cover a display surface IS of the display module DM. The window WP may include an optically transparent insulating material. In an embodiment, for example, the window WP may include glass or plastic. The window WP may have a single- or multi-layered structure. In an embodiment, for example, the window WP may have a stacked structure of a glass substrate and a plastic film which are coupled or attached to each other by an adhesive.

The window WP includes a front surface FS exposed to the outside. A front surface of the electronic device ED may be substantially defined by the front surface FS of the window WP. The front surface FS of the window WP may include a transmission region TA with high light transmittance, and a bezel region BZA with low light transmittance.

In an embodiment, the transmission region TA may be an optically transparent region. The transmission region TA may have a shape corresponding to a display region DA. In an embodiment, for example, the transmission region TA overlaps an entire surface or at least a portion, of the display region DA. An image IM displayed in the display region DA of the display module DM may be visible from the outside through the transmission region TA.

The bezel region BZA may be a region with relatively low light transmittance compared to the transmission region TA. The bezel region BZA defines a shape of the transmission region TA. The bezel region BZA may be adjacent to the transmission region TA and may surround the transmission region TA.

The bezel region BZA may have a predetermined color. In an embodiment where the window WP is provided as a glass or plastic substrate, the bezel region BZA may be a region formed by a color layer printed or deposited on one surface of the glass or plastic substrate. Alternatively, the bezel region BZA may also be formed by coloring the corresponding region of the glass or plastic substrate. The bezel region BZA may cover a non-display region NDA of the display module DM to block the non-display region NDA from being viewed from the outside.

The display module DM may display the image IM and sense an external input. The display module DM may include the display region DA and the non-display region NDA which are distinguished on a plane. The display region DA may be activated in response to an electrical signal. In such an embodiment, the display region DA may be a region where the image IM is displayed, and simultaneously a region where the external input is sensed. However, this is merely an example, and within the display region DA, a region where the image is displayed and a region where the external input is sensed may be separated from each other, and is not limited to any one embodiment.

The non-display region NDA is adjacent to the display region DA. In an embodiment, for example, the non-display region NDA may surround an edge of the display region DA. However, this is merely an example. The non-display region NDA may be adjacent to only a portion of the edge of the display region DA, and is not limited to any one embodiment.

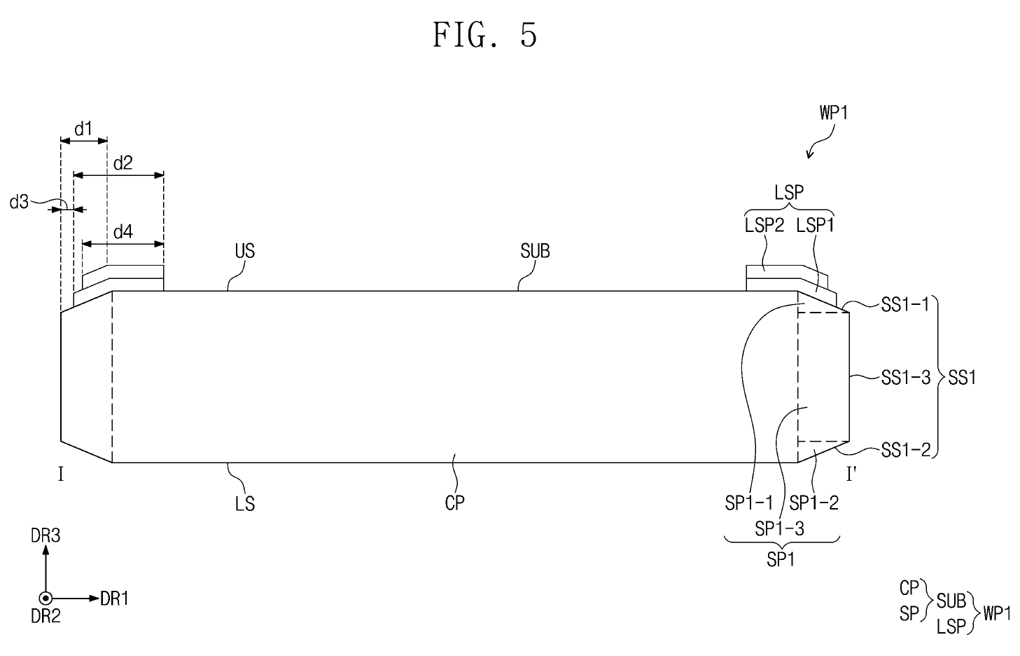

FIG. 5 is a cross-sectional view taken along line I-I' of a window according to an embodiment.

In an embodiment, a window WP1 may include a substrate SUB and a light-blocking pattern LSP. The substrate SUB may be a glass substrate, and may transmit light output from the display module DM (see FIG. 4) to be visible. The light-blocking pattern LSP may be disposed in a partial region of the substrate SUB to block leaking light. The light-blocking pattern LSP may define the bezel region BZA (see FIG. 4) in FIG. 4.

The substrate SUB may have a central portion CP and a side portion SP1. The side portion SP1 may be disposed on an outer portion of the window WP1 compared to the central portion CP. In an embodiment, the side portion SP1 may have a smaller thickness than the central portion CP. Here, the central portion CP and the side portion SP1 are defined by or corresponding to the portions of the substrate SUB, and the central portion CP and the side portion SP1 may have an integrated shape or be integrally formed as a sing unitary indivisible part. A size of the window WP1 is determined by a size of the substrate SUB.

The central portion CP may mean a central region of the substrate SUB. The central portion CP may be defined as a region, of the substrate SUB, with a constant thickness. The central portion CP may include an upper surface US and a lower surface LS opposite to the upper surface US. Surfaces, among the surfaces of the substrate SUB, substantially disposed in parallel to a surface defined by a first direction DR1 and a second direction DR2, and spaced apart in a third direction DR3 are respectively defined as the upper surface US and the lower surface LS. The upper surface US and the lower surface LS may be substantially parallel to each other, allowing a thickness of the central portion CP to be constant.

The side portion SP1 may be disposed adjacent to at least one side of the central portion CP to define an edge (or an edge portion) of the substrate SUB. The side portion SP1 may be defined as a region where a thickness of the substrate SUB decreases as the side portion SP1 becomes further away from the central portion. The side portion SP1 may correspond to an outer region of the substrate SUB, and specifically, may be defined as a region from a boundary where the thickness of the substrate SUB changes to the edge of the substrate SUB. The boundary where the thickness of the substrate SUB changes may be a boundary between the central portion CP and the side portion SP1.

The side portion SP1 may have a frame shape surrounding all four sides of the central portion CP on a plane or in a plan view (or when viewed in the third direction DR3). Accordingly, four sides of the window WP may each be defined by the side portion SP1. However, this is merely an example, and the side portion SP1 may be disposed only at any one side of the central portion CP and is not limited to any one embodiment.

A width d1 of the side portion SP1 may be a value measured in a direction where the side portion SP is spaced apart from (a center of) the central portion CP. In an embodiment, as shown in FIG. 5, since the side portion is spaced apart from the central portion in the first direction DR1 or a direction opposite to the first direction DR1, the width of the side portion may be a value measured in the first direction DR1. The width d1 of the side portion SP1 may be defined as a length from a boundary between the upper surface US and a side surface SS1 to the edge of the side portion SP1 on a plane. In an embodiment, the width d1 of the side portion SP1 may be about 0.1 millimeter (mm) or less, and for example, may be about 0.08 mm.

The side portion SP1 may include a first portion SP1-1, a second portion SP1-2, and a third portion SP1-3. The first portion SP1-1, the second portion SP1-2, and the third portion SP1-3 may be regions that divides the side portion SP1 in the third direction DR3. The third portion SP1-3 may be disposed on the second portion SP1-2, and the first portion SP1-1 may be disposed on the third portion SP1-3.

The first portion SP1-1 may be a region connected to the upper surface US, and may be a region located at an uppermost side of the side portion SP1. The first portion SP1-1 may be a region of which a width increases as moving in the first direction DR1 that is the direction where the side portion SP1 is spaced apart from the central portion CP. The second portion SP1-2 may be a region connected to the lower surface LS, and may be a region located at a lowermost side of the side portion SP1. The second portion SP1-2 may be a region of which a width increases as moves in the first direction DR1 further away from the central portion CP. Here, the width of the first portion SP1-1 and the second portion SP1-2 may be a thickness thereof in the first direction DR1. That is, the first portion SP1-1 and the second portion SP1-2 may be regions having a thickness decreasing as moving in the first direction DR1. The third portion SP1-3 may be disposed between the first portion SP1-1 and the second portion SP1-2. The third portion SP1-3 may be substantially parallel to the second direction DR2 and defined as a region of which a width is constant in the first direction DR1.

A surface defined by the side portion SP1 may be defined as the side surface SS1. The side surface SS1 may be disposed between the upper surface US and the lower surface LS. Even when the surface is located at an upper side of the substrate in the third direction DR3, the surface is defined as the side surface SS1 when the surface is not substantially parallel to the first direction DR1 and the displacement occurs in the third direction DR3. The side surface SS1 may include a first side surface SS1-1, a second side surface SS1-2, and a third side surface SS1-3. The first side surface SS1-1, the second side surface SS1-2, and the third side surface SS1-3 may be respectively defined as the surfaces of the first portion SP1-1, the second portion SP1-2, and the third portion SP1-3.

The first side surface SS1-1 may be a slope (or inclined) surface extending from the upper surface US. The second side surface may be a slope surface extending from the lower surface LS. The third side surface SS1-3 may connect the first side surface SS1-1 and the second side surface SS1-2, and may be a surface perpendicular to the upper surface US and the lower surface LS. In such an embodiment, the edge of the window may be defined by the third side surface SS1-3.

The light-blocking pattern LSP may be disposed on the upper surface US of the central portion CP and the first side surface SS1-1 of the side portion SP1. The light-blocking pattern LSP may extend along the edge of the substrate SUB on a plane in the first direction DR1 or the second direction DR2. Referring to the window WP in FIG. 4, the light-blocking pattern LSP may be disposed substantially parallel to the edge of the window WP (see FIG. 4). The light-blocking pattern LSP may define the bezel region BZA (see FIG. 4) of the window WP (see FIG. 4). A length d2 of the light-blocking pattern LSP in the first direction DR1 may correspond to the width of the bezel region BZA (see FIG. 4).

In an embodiment, the light-blocking pattern LSP may not overlap at least a portion of the side portion SP1 on a plane. In an embodiment, for example, a spaced distance d3 between (an end of) the light-blocking pattern LSP and (an end of) the third side surface SS1-3 may be about 0.02 mm or less. That is, a portion of the first side surface SS1-1 may be exposed from the light-blocking pattern LSP. However, this is merely an example, and the light-blocking pattern LSP may entirely overlap or cover the side portion SP1 on a plane. Here, an edge of the light-blocking pattern LSP may be aligned with the third side surface SS1-3 on a cross section. A first light-blocking pattern LSP1 may determine a width of the light-blocking pattern LSP.

The light-blocking pattern LSP may have a single- or multi-layered structure. FIG. 5 illustrates an embodiment where the light-blocking pattern LSP is formed in two layers. In such an embodiment, the light-blocking pattern LSP may include the first light-blocking pattern LSP1 and a second light-blocking pattern LSP2. The second light-blocking pattern LSP2 may be disposed on the first light-blocking pattern LSP1. An edge, which is adjacent to the central portion of the substrate SUB, among the edges of the second light-blocking pattern LSP2 may be aligned with an edge, which is adjacent to the central portion of the substrate SUB, among the edges of the first light-blocking pattern LSP1. That is, innermost edges of the first light-blocking pattern LSP1 and the second light-blocking pattern LSP2 on a same side may be vertically aligned with each other in the third direction DR3.

An edge, adjacent to the edge of the substrate SUB, among the edges of the second light-blocking pattern LSP2 may be disposed further away from the edge of the substrate SUB than an edge, adjacent to the edge of the substrate SUB, among the edges of the first light-blocking pattern LSP1. That is, an outermost edge of the second light-blocking pattern LSP2 may be disposed further outwardly than an outermost edge of the first light-blocking pattern LSP1 on a same side may be vertically aligned with each other in the third direction DR3. In an embodiment, for example, the second light-blocking pattern LSP2 may be formed to have a smaller width than the first light-blocking pattern LSP1 on a plane, and a region where the second light-blocking pattern LSP2 does not overlap the first light-blocking pattern LSP1 may be defined. The region where the second light-blocking pattern LSP2 does not overlap the first light-blocking pattern LSP1 may be disposed on the side portion SP1. The region where the second light-blocking pattern LSP2 does not overlap the first light-blocking pattern LSP1 may be substantially parallel to the third side surface SS1-3. In an embodiment, as shown in FIG. 5, the first light-blocking pattern LSP1 and the second light-blocking pattern LSP2 may have a constant thickness, but the thickness thereof may become smaller as being closer to the edge of the substrate SUB.

In such an embodiment, as the light-blocking pattern LSP is printed closer to the edge of the substrate SUB and covers wide area of the first side surface SS1-1, a light leakage phenomenon when driving a display may be minimized.

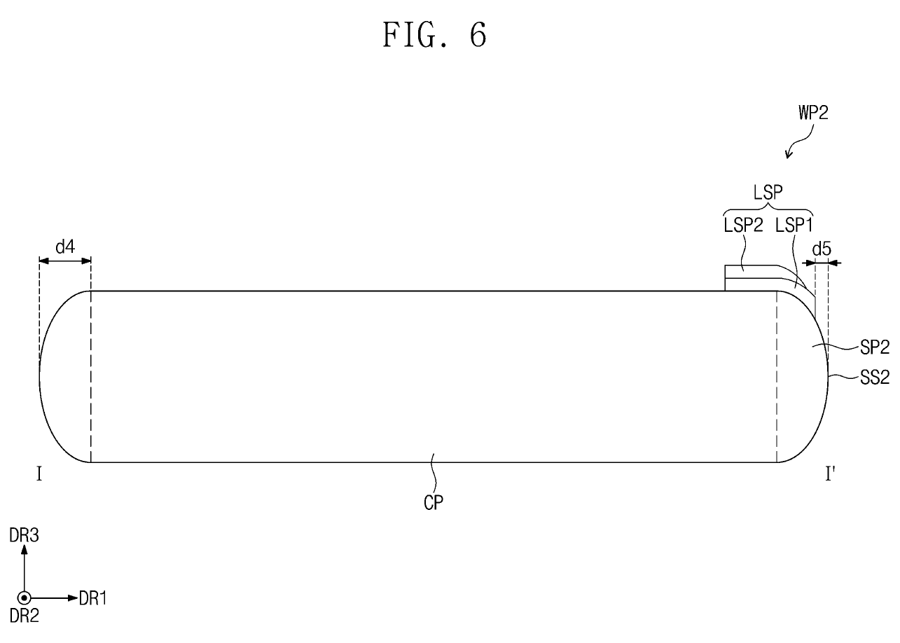

FIG. 6 is a cross-sectional view taken along line I-I' of a window according to an embodiment.

FIG. 6 illustrates an embodiment of a window WP2 where a side surface SS2 of a substrate SUB is defined to have a curved surface.

In an embodiment where the side surface SS2 is defined to have the curved surface, ink that constitutes a light-blocking pattern LSP may spread more easily than in a case where the side surface SS1 (see FIG. 5) is formed to have the slope surface. When a width d4 of a side portion SP2 is the same as the width d3 (see FIG. 5) of the side portion SP1 (see FIG. 5), the light-blocking pattern LSP may be wider on the side portion SP2 where the side surface SS2 is defined to have the curved surface. In an embodiment where the side surface SS2 is defined to have the curved surface, the width d4 of the side portion SP2 may be about 0.1 mm or less, and for example, may be about 0.08 mm.

When the side portion SP2 has a curved surface, a width d5 of a region where the light-blocking pattern LSP1 is not printed may be in a range from about 0 mm to about 0.02 mm.

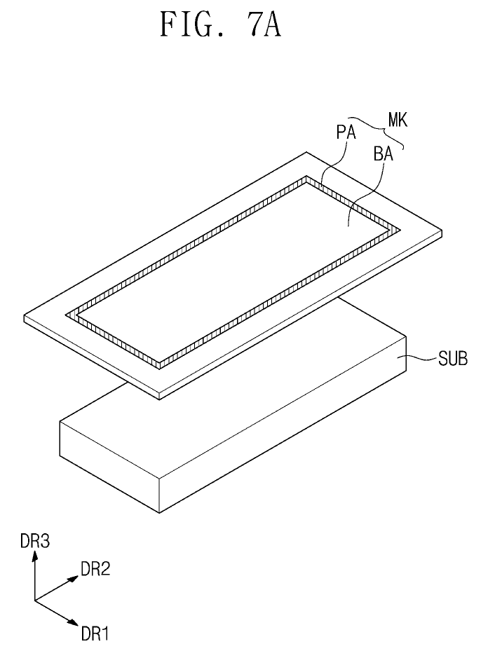

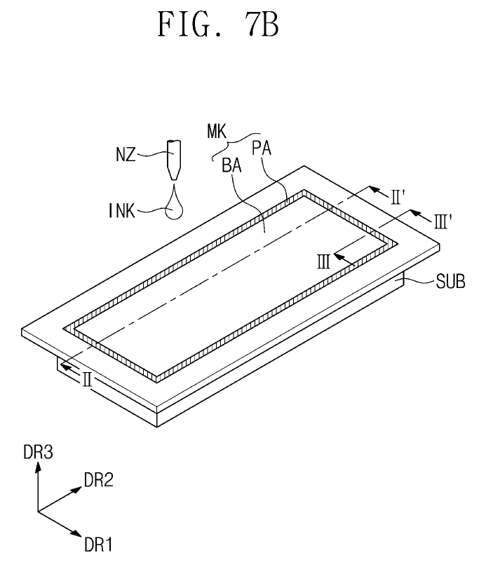

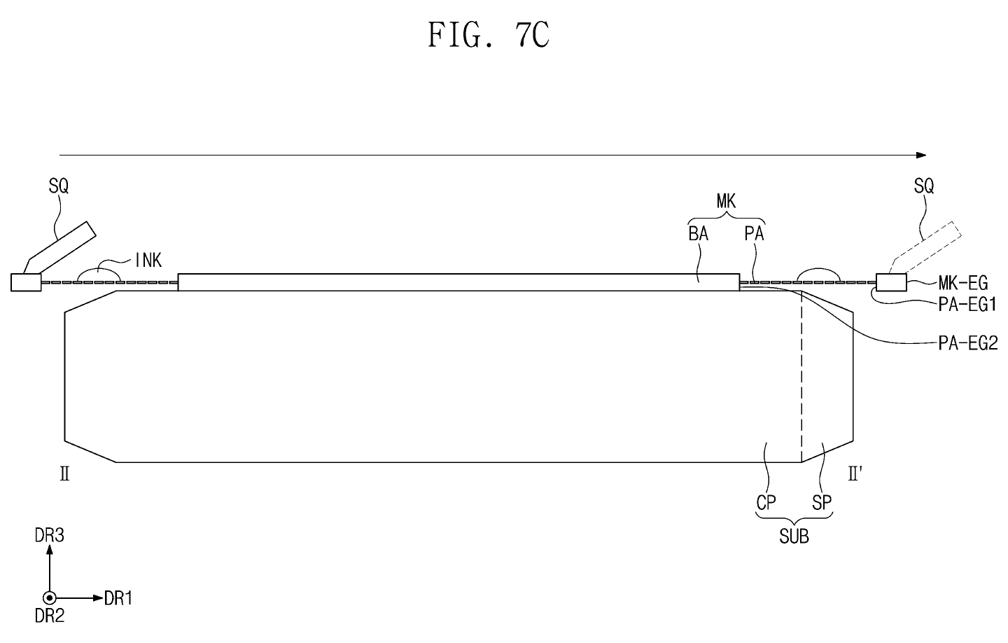

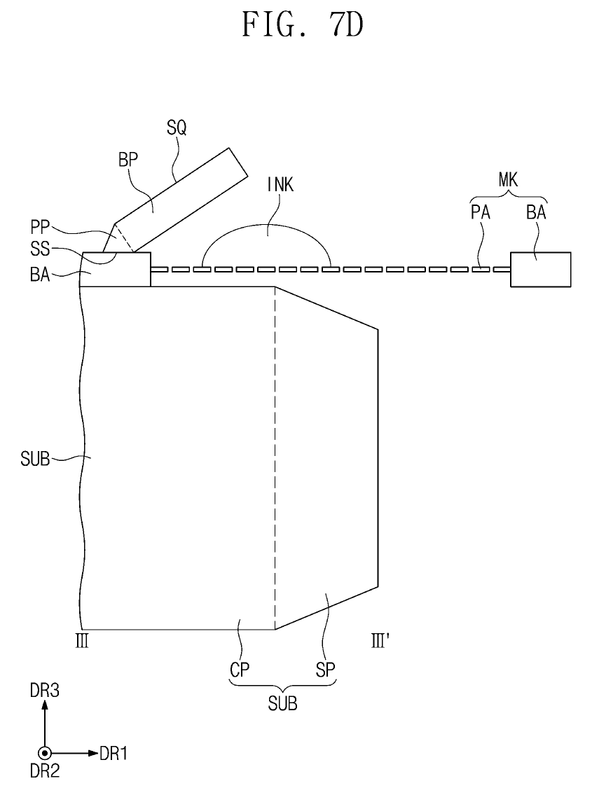

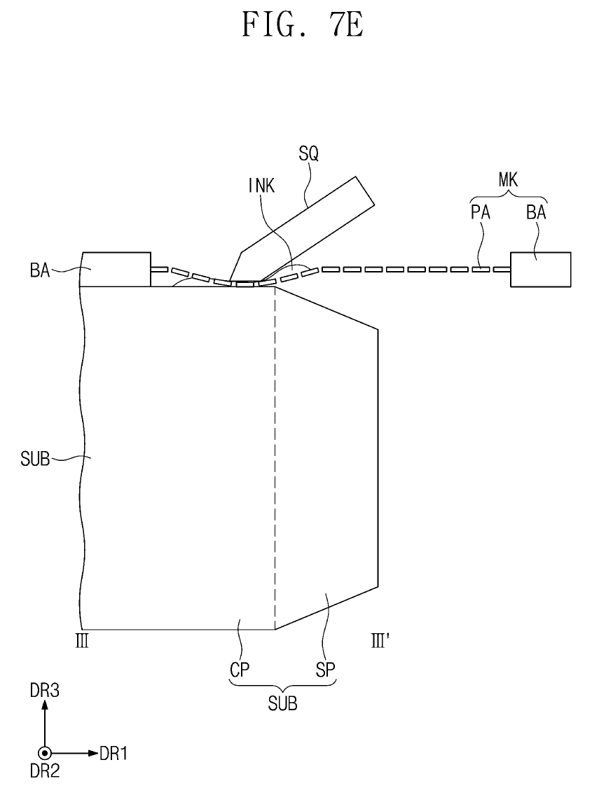

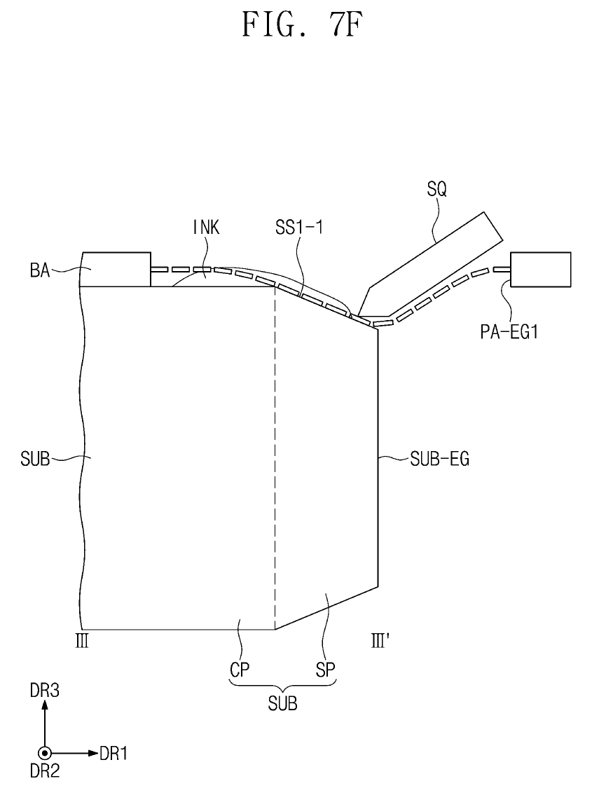

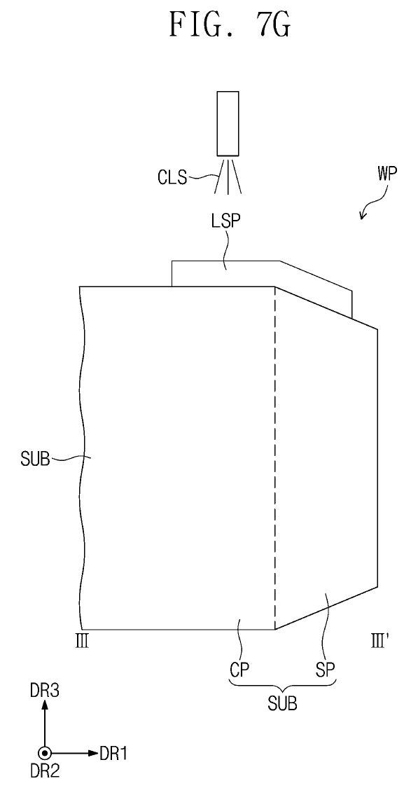

The light-blocking pattern LSP according to an embodiment of the invention may be printed using a mask MK (see FIG. 7A) to be described later, thereby having an improved print quality. Accordingly, the region where the light-blocking pattern LSP is not printed may be formed to have a width of about 0.02 mm or less, and thus the light-blocking pattern with sufficient area may be formed.

Since the light-blocking pattern LSP according to an embodiment of the invention is formed using the mask MK (see FIG. 7A) to be described later, even a surface with slope or curve may be reliably printed. The light-blocking pattern LSP may be evenly formed even on a non-planar surface. Therefore, the window according to an embodiment of the invention may include the light-blocking pattern having a sufficient area regardless of the curved or angled shape of the side surface.

FIGS. 7A to 7G are cross-sectional views illustrating a method for manufacturing a window according to an embodiment of the invention. In description of embodiments with reference to FIGS. 7A to 7G, the same or like components as the components described above with reference to FIGS. 1 to 6 will be denoted as the same/similar reference numerals or characters, and any repetitive detailed thereof will be omitted or simplified.

Referring to FIG. 7A, in an embodiment of a method for manufacturing a window, a mask MK may be provided on a substrate SUB. The substrate SUB may be a glass substrate. A side portion SP (see FIG. 7C), which decreases in thickness during a process where the substrate SUB is separated from a mother substrate, may be formed in the substrate SUB. In such an embodiment, a shape of the side portion correspond to the shape illustrated in FIGS. 5 and 6. A width of the side portion is formed to be smaller than that of the entire substrate and is represented in a rectangular shape as shown in FIG. 7A.

The mask MK may be provided to form a light-blocking pattern on the substrate SUB. The mask MK includes a blocking region BA where transmission of ink is blocked and a printing region PA through which ink is transmitted. The blocking region BA may correspond to a central portion CP (see FIG. 7C) of the substrate SUB, and the printing region PA may correspond to the side portion SP (see FIG. 7C) of the substrate SUB. In an embodiment, as shown in FIG. 7A, the printing region PA has a closed loop-shape to correspond to an edge region of the substrate SUB, but the printing region may be defined differently depending on a region printed on the substrate SUB, and the mask MK with the printing region PA defined only on a partial edge may be used depending on a printing method.

The blocking region BA of the mask MK is disposed in a region corresponding to a non-printing region in the substrate SUB. The blocking region BA may be defined not only in a central region of the substrate SUB but also outside the printing region.

Referring to FIG. 7B, in an embodiment of a method for manufacturing a window, the mask MK is disposed on the substrate SUB. The mask MK may be larger than the substrate SUB. The mask MK is formed to be larger (e.g., wider in width or longer in length) than the substrate SUB, and the printing region PA of the mask MK corresponds to an edge of the substrate SUB. In a state where the mask MK is disposed, ink INK is ejected through a nozzle NZ and provided onto the printing region.

The ejected ink INK may include a color component. In an embodiment, for example, the ink INK may be a material including black pigment or black dye. The ink INK then determines a color of a light-blocking pattern, and may allow a window to have a light-blocking effect.

FIG. 7C illustrates a process of preparing a squeegee SQ to print the ink INK onto the substrate SUB. FIG. 7C illustrates a cross section taken along line II-II' of FIG. 7B. FIG. 7C illustrates a state in which the ink INK has been ejected on the printing region PA of the mask MK, and before the ink is printed onto the substrate SUB.

In an embodiment of a method for manufacturing a window, the squeegee SQ may be disposed on the mask MK. The squeegee SQ may mean a tool used to push ink evenly in a lithographic printing or screen printing process. The squeegee SQ may pressurize the mask MK while moving in one direction.

The printing region PA may be formed to correspond to two side portions SP of the substrate SUB on a cross section.

The printing region PA may cover the side portion SP, and may be formed to be larger than the side portion SP. That is, the printing region PA may include a region that does not overlap the side portion SP. in an embodiment, the printing region PA may have two edges PA-EG1 and PA-EG2 which are substantially parallel in a first direction DR1 and extend in a second direction DR2. A first edge PA-EG1 is disposed closer to an edge MK-EG of the mask MK, and a second edge PA-EG2 is disposed further away from the edge MK-EG of the mask MK. The first edge PA-EG1 may not overlap the substrate SUB in a state where the mask MK is disposed on the substrate SUB. The second edge PA-EG2 may overlap the substrate SUB, or an upper surface US of the central portion CP. Accordingly, the printing region PA may be disposed on the side portion SP and a partial region of the central portion CP.

Hereinafter, a process where the squeegee SQ in FIG. 7C moves to pressurize the printing region PA, and transmits the ink INK onto the substrate SUB will be described with reference to FIGS. 7D to 7F.

FIGS. 7D to 7F illustrate cross sections taken along line III-III' of FIG. 7B.

Referring to FIG. 7D, the ink INK disposed on the substrate SUB may be located on the printing region PA, before being pressurized onto the printing region PA by the squeegee SQ.

According to an embodiment of the invention, the squeegee SQ includes a body portion BP and a protruding portion PP which protrudes from the body portion BP and has a smaller thickness than the body portion BP. The body portion BP may have a rectangular shape on a cross section. The protruding portion PP may include a slope surface SS extending from the body portion BP and inclined from one surface of the body portion BP. In an embodiment, the angle between the slope surface SS of the squeegee SQ and the one surface of the body portion BP may be in a range from about 120 degrees to about 135 degrees, but an angle between the slope surface SS of the squeegee SQ and the one surface of the body portion BP is not particularly limited. However, a printing method according to an embodiment of the invention may be provided by a form with one surface in contact with the mask MK, other than the form of embodiments of the squeegee SQ illustrated in the drawings.

The squeegee SQ may pass the blocking region BA and the printing region PA sequentially and repeatedly by moving in one direction on the mask MK. The squeegee SQ may pressurize the mask MK with the slope surface SS.

FIG. 7E illustrates a moment when the squeegee SQ is pressurizing the printing region PA.

The printing region PA of the mask MK may include a flexible mesh pattern. When the squeegee SQ pressurizes the printing region PA of the mask MK, the printing region PA may be deformed in a direction toward the substrate SUB. Here, the wording “being deformed” may mean that areas of openings defined by the mesh become expanded as the mesh pattern is stretched.

When a space between the mesh patterns of the printing region PA increases as the squeegee SQ pressurizes the printing region PA, the ink located on the printing region PA may pass through the mesh pattern and move to the substrate SUB. The ink INK may move to the substrate SUB and spread. A region where the ink INK spreads may be limited by the blocking region BA of the mask MK, and an edge of the ink INK may spread evenly.

As the squeegee SQ pressurizes the printing region PA with the slope surface SS, the printing region PA may further increase an amount of the ink INK moving onto the substrate SUB. Accordingly, the amount of the ejected ink INK may further be increased, which makes it possible to print on a larger area.

Referring to FIG. 7F, the mesh pattern may be bent along the side portion SP, and the squeegee SQ may pressurize the printing region PA along the side portion SP from the central portion CP such that the printing region PA is bent along the side portion SP. Since the squeegee SQ moves while pressurizing, at least a portion of the printing region PA is in contact with a first side surface SS1-1 of the substrate SUB when the squeegee SQ pressurizes the printing region PA.

The first edge PA-EG1 of the printing region PA may not overlap the substrate SUB and may be disposed further away from the substrate SUB than an edge SUB-EG of the substrate SUB, and thus the printing region PA may cover up to the first side surface SS1-1 of the substrate SUB. Accordingly, the ink INK may be applied closer to the edge SUB-EG of the substrate SUB.

Referring to FIG. 7G, in an embodiment of a method for manufacturing a window, the applied ink INK is cured by a light source CLS to form a light-blocking pattern LSP. A window WP including the light-blocking pattern LSP and the substrate SUB is formed. The light-blocking pattern LSP formed through FIGS. 7A to 7G may correspond to the first light-blocking pattern LSP1 in FIG. 5.

After the ink INK is cured, a light-blocking pattern may further be formed on the light-blocking pattern LSP by repeating the processes, which are described with reference to FIGS. 7A to 7G, again. Here, another mask with the printing region of a different size may be used. In an embodiment where a process of forming a second light-blocking pattern by using a second mask with a smaller printing region is further performed, the window WP1 illustrated in FIG. 5 may be formed. As illustrated in FIG. 5, the second light-blocking pattern may expose at least a partial region of the first light-blocking pattern disposed on the side portion.

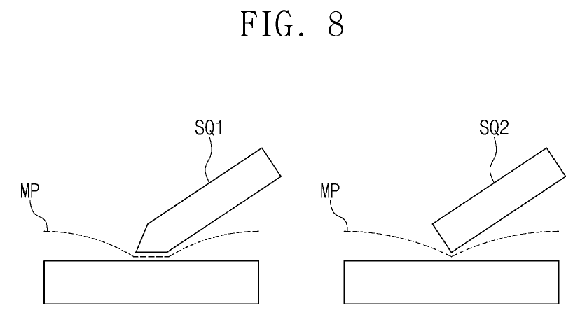

FIG. 8 illustrates Comparative Examples of a squeegee according to an embodiment of the invention.

A surface contact squeegee SQ1 according to an embodiment of the invention pressurizes a mesh pattern MP with one surface. The surface contact squeegee SQ1 pressurizing the mesh pattern MP with the surface may press a printing region PA more widely than a line contact squeegee SQ2 pressurizing the mesh pattern MP with a corner (i.e., a vertex or an edge). Printing performance may be further improved even when the surface contact squeegee SQ1 moves at an equal speed. Referring to back FIG. 7E, since the squeegee SQ (see FIG. 7E) with the slope surface SS (see FIG. 7D) is used, more amount of the ink may be printed onto the substrate SUB, and a printing thickness and printing region of the ink INK may increase. Accordingly, the light-blocking region LSP (see FIG. 5) may be manufactured such that a non-printed region decreases or the non-printed region does not exist on the edge of the substrate SUB.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method for manufacturing a window, the method comprising:
providing a substrate including a central portion and a side portion having a smaller thickness than the central portion on a plane; and
forming a first light-blocking pattern on the substrate,
wherein the forming the first light-blocking pattern includes
disposing a mask on the substrate, wherein the mask includes a printing region with a plurality of mesh patterns corresponding to the side portion and a portion of the central portion and a blocking region corresponding to a remaining portion of the central portion,
providing ink on the printing region, and
printing the ink on the substrate by using a squeegee which includes a body portion and a protruding portion having a slope surface inclined from one surface of the body portion and having a smaller thickness than the body portion.

2. The method of claim 1, wherein in the printing the ink on the substrate, the squeegee pressurizes the mask while moving in one direction.

3. The method of claim 1, wherein an angle between the slope surface of the squeegee and the one surface of the squeegee is in a range from about 120 degrees to about 135 degrees.

4. The method of claim 1, wherein
the printing region of the mask is flexible, and
the squeegee pressurizes the printing region along one direction such that the printing region is bent along the side portion.

5. The method of claim 4, wherein the ink passes through the mesh pattern of the printing region, which is bent, and is printed onto the central portion and the side portion.

6. The method of claim 1, wherein a width of a region, of the side portion of the substrate, exposed by the first light-blocking pattern is about 0.02 mm or less.

7. The method of claim 1, wherein the printing region comprises a region which overlaps the substrate and a region which does not overlap the substrate.

8. The method of claim 1, wherein a thickness of the side portion decreases as being away from the central portion.

9. The method of claim 8, wherein a width of the side portion in a direction where the side portion is spaced apart from the central portion is about 0.08 mm.

10. The method of claim 8, wherein the side portion comprises a curved surface connected to the central portion.

11. The method of claim 8, wherein the side portion of the substrate comprises a first portion connected to an upper surface of the central portion, a second portion connected to a lower surface of the central portion, and a third portion disposed between the first portion and the second portion, and
a thickness of the first portion decreases as the side portion becomes further away from the central portion,
a thickness of the second portion decreases as the side portion becomes further away from the central portion, and
a width of the third portion is constant as the side portion becomes further away from the central portion.

12. The method of claim 1, further comprising forming a second light-blocking pattern on the first light-blocking pattern,
wherein the forming the second light-blocking pattern is formed by using an additional mask with a mesh pattern having a smaller than the mesh pattern of the mask.

13. The method of claim 12, wherein the second light-blocking pattern exposes at least a partial region of the first light-blocking pattern disposed on the side portion.

14. The method of claim 1, wherein the first light-blocking pattern corresponds to all edges of the substrate.

15. A display device comprising:
a window; and
a display module disposed on a lower surface of the window,
wherein the window includes a substrate which has a central portion and a side portion having a smaller thickness than the central portion on a plane, and a light-blocking pattern disposed on the central portion and the side portion,
the central portion includes an upper surface and a lower surface opposite to the upper surface, and the side portion includes a side surface disposed between the upper surface and the lower surface,
a thickness of the side portion of the substrate decreases as being away from the central portion, and a width of the side portion in one direction where the side portion is spaced apart from the central portion is about 0.08 mm or less, and
a width of a region of the side surface, which does not overlap the light-blocking pattern, in the one direction is about 0.02 mm or less.

16. The display device of claim 15, wherein the side surface comprises a plurality of planar surfaces, and
the plurality of planar surfaces include a first slope surface connected to the upper surface, a second slope surface connected to the lower surface, and a vertical surface connected between the first slope surface and the second slope surface.

17. The display device of claim 15, wherein the side surface is a curved surface.

18. The display device of claim 15, wherein the light-blocking pattern overlaps a boundary between the upper surface of the central portion and the side surface of the side portion.

19. The display device of claim 18, wherein the light-blocking pattern extends along an edge of the substrate on the central portion.

20. An electronic device comprising:
a display device;
a power module; and
a processor,
wherein the display device includes a window and a display module disposed on a lower surface of the window,
the window includes a substrate which includes a central portion and a side portion having a smaller thickness than the central portion on a plane, and a light-blocking pattern disposed on the central portion and the side portion,
the central portion includes an upper surface and a lower surface opposite to the upper surface, and the side portion includes a side surface disposed between the upper surface and the lower surface,
a thickness of the side portion decreases as being away from the central portion, and a width of the side portion on a plane is about 0.08 mm or less, and
a width of a region where the light-blocking pattern does not overlap the side portion is about 0.02 mm or less on a plane.
